(19) United States
(12) Patent Application Publication
(10) Pub. No.: US 2008/0072119 A1
(43) Pub. Date: Mar. 20, 2008

(54) Allowable bit errors per sector in memory devices

(76) Inventor: Rodney Rozman, Placerville, CA (US)

Correspondence Address: TROP, PRUNER & HU, P.C., 1616 S. VOSS RD., SITE 750, HOUSTON, TX, 77057-2631, US

(21) Appl. No.: 11/515,048

(22) Filed: Aug. 31, 2006

(51) Int. Cl. G11C 29/00

(52) U.S. Cl. 714/763

(57) ABSTRACT

A method of reading a page from a memory array, wherein the page includes a plurality of sector, determining whether each of the plurality of sectors includes an allowable number of errors, and providing a success indicator if each of the plurality of sectors includes an allowable number of errors.

### FIELD

Embodiments of the present invention relate to the use of Error Control Coding (ECC) for memory devices.

### BACKGROUND

In a system supporting Error Control Coding (ECC), flash memory devices may allow up to 1 bit per page (2112 bytes) to fail during write operations while still considering the write operation a success. However, if more than 1 bit per page fails, the write operation will be considered a failure and the memory device may be considered to be non-functional. This can contribute to yield losses in manufacturing or may cause failure of an end-user device or system due to non-recoverable single bit errors in memory.

### BRIEF DESCRIPTION OF THE DRAWINGS

A better understanding of the present invention can be obtained from the following detailed description in conjunction with the following drawings, in which:

FIG. 1 is an illustration of memory device according to some embodiments.

FIG. 2 is a flow diagram illustrating bit error sensing and verification for program and/or erase operations in a memory device according to some embodiments.

FIG. 3 is an illustration of a page of memory according to some embodiments.

FIG. 4 is an illustration of a system according to some embodiments.

### DETAILED DESCRIPTION

In the following description, for purposes of explanation, numerous details are set forth in order to provide a thorough understanding of embodiments of the present invention. However, it will be apparent to one skilled in the art that these specific details are not required in order to practice the present invention as hereinafter claimed.

As used herein, a “page” is defined as a programmable region in the memory array of a memory device. Typically, a page consists of 2,112 bytes, however, a page may be larger or smaller than 2,112 bytes. A page may include a 2,048 byte data storage region and a separate 64 byte region. The separate 64 byte region may be used for error management functions.

Each page may be further divided into four “sectors” or “codewords.” A sector or codeword is defined as a 512 byte data storage region. Each 512 byte sector may be associated with a corresponding separate error management region of up to 16 bytes, for a total of up to 528 bytes allocated to each sector.

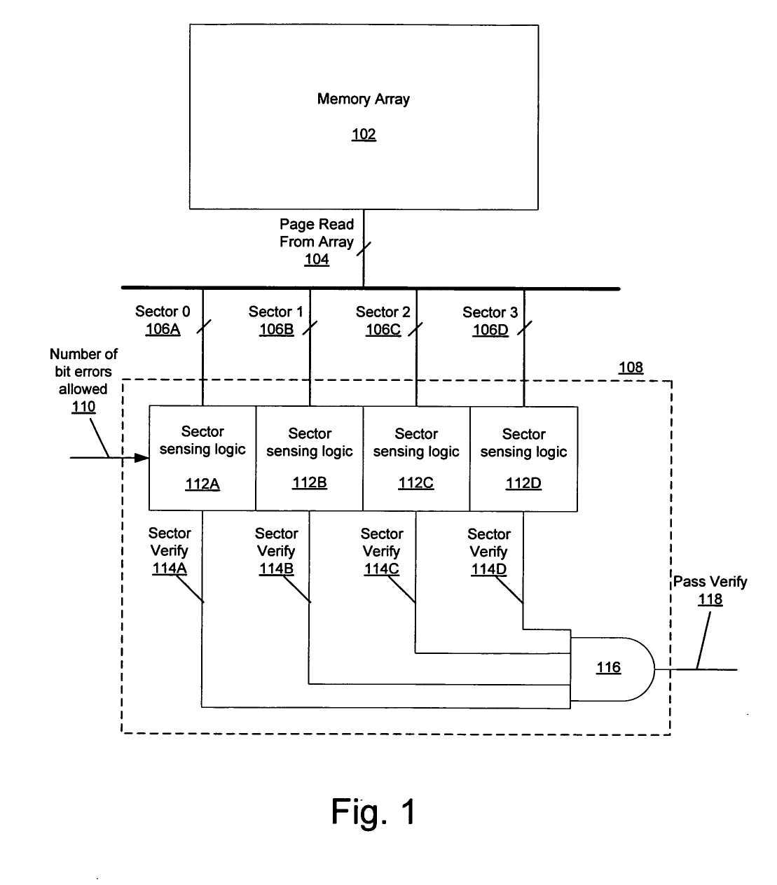

FIG. 1 illustrates a memory device that is capable of detecting and allowing one or more single bit errors per sector according to some embodiments. The memory device includes a memory array (102) to store data. In some embodiments, the memory device may be a NAND flash memory device. In other embodiments, the memory device may be another type of memory device that is capable of using an ECC scheme, such as, but not limited to, for example, Ovonic Unified Memory (OUM) or polymer memory.

After a page in the memory array is programmed or erased, a verify or status operation may be performed to determine whether the program or erase operation was successful. During a verify operation, a page (104) is read from the array.

The page (104) read from the array may be split into sectors (106A-D). In some embodiments, the sectors may be pre-defined as sequential 512 KB portions of each page. In other embodiments, the sectors may be defined differently.

Sector sensing logic (112A-D) coupled to the memory array may then determine whether each sector of the page includes an acceptable number of bit errors (110). An acceptable number of errors is defined as a number of errors per sector that is less than or equal to the maximum number of errors that may be corrected in each sector using ECC. The acceptable number of errors per sector, N, may set by a user or by the system. This number may be programmed to and/or stored in a register, such as a configuration register, or may be set using programmable fuses in the memory device.

The acceptable number of errors per sector should be less than or equal to the number of bits that can be corrected by the ECC scheme used in the system. For example, in a system that implements a Hamming ECC scheme that can correct a maximum of one bit error per sector, the acceptable number of errors per sector should be set to one. In a system that implements an ECC scheme that is capable of correcting multiple bit errors per sector, the acceptable number of errors per sector may be any number up to and including the maximum number of bit errors that may be corrected using the system's ECC scheme.

Each sector sensing circuit (112A-D) senses any bit errors in each sector. These bit errors may then be summed, for example, using an adder, to determine the total number of bit errors per sector. The total number of bit errors per sector may then be compared to the system selectable acceptable number of bit errors (110), for example, using a comparator. For each sector, if the total number of bit errors is greater than an acceptable number of bit errors, the sector verify signal (114A-D) for the sector will indicate that the sector has failed. If the total number of bit errors in a sector is an acceptable number of bit errors the sector verify signal (114A-D) for the sector will indicate that the sector has passed.

If all sectors in a page pass, that is, if each sector has an acceptable number of errors, the program or erase operation will be deemed successful. In some embodiments, determining whether all sectors in a page pass may be determined using an AND gate (116) within the sensing logic (108), which performs a logical AND operation on each of the sector verify signals (114A-D).

The success or failure of the program or erase operation may be indicated by a pass verify signal (118), which may in some embodiments be the output of an AND gate (116). The pass verify signal (118) will indicate that a page program or erase operation was a success when each of the sectors in the page contains an acceptable number of bit errors. The pass verify signal (118) will indicate that a page program or erase operation was a failure when one or more of the sectors in the page contains more than an acceptable number of bit errors.

When the pass verify signal indicates that the program or erase operation was a success, and one or more sectors include bit errors, an ECC scheme may subsequently be used to correct the bit errors in each sector. In some embodiments, ECC error correction will be performed by a hardware or software module that is separate from the memory device. In other embodiments, the error correction may be performed by logic within the flash memory device or by code stored on the flash memory device.

Thus, the sector error sensing logic may permit one or more bit errors per sector of each page during a program or erase operation, and the operation will still be considered successful.

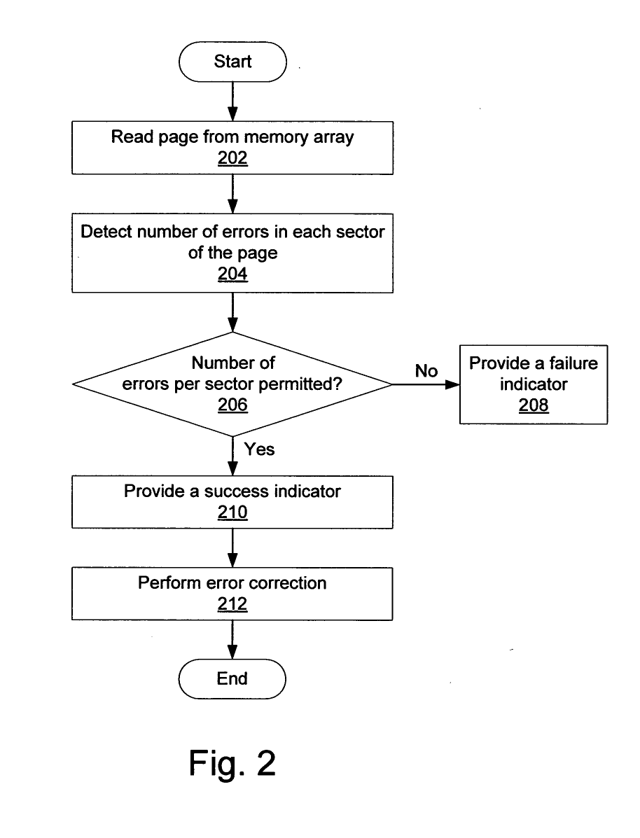

FIG. 2 is a flow diagram of a program or erase verify operation according to some embodiments. To verify that a program or erase has successfully executed, the page that has been programmed or erased is read from the memory array (202).

After the page is read, sensing logic may be used to detect the total number of errors in each sector of the page (204). The number of errors in each sector may be compared to a maximum allowable number of errors per sector in order to determine whether each sector includes an acceptable number of errors. If any one of the sectors in the page has greater than an acceptable number of errors, a failure indicator will be provided to indicate that the program or erase operation failed (208). If each sector in the page contains an acceptable number of errors, a success indicator will be provided to indicate that the program or erase operation was a success (210). As described above with respect to FIG. 1, the maximum allowable number of errors per sector may be set by a user, and should be a number that is less than or equal to the number of errors that may be corrected by the system using an ECC algorithm.

The success (210) or failure (208) indicator may further be written to a register, such as, for example, a status register.

If the program or erase operation was successful, but one or more sectors in the page contained one or more bit errors, error correction may be subsequently performed using the system's ECC scheme (212). The ECC operation may, in some embodiments, be performed by hardware or software external to the memory device.

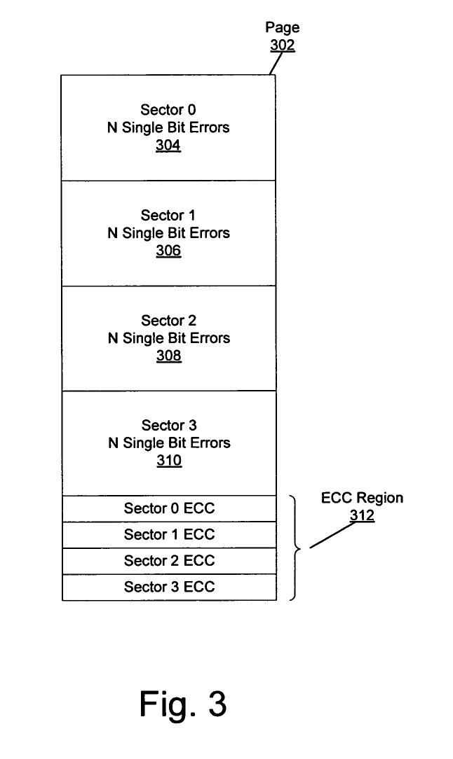

FIG. 3 illustrates the maximum number of single bit errors in a page of memory (302) after a program or erase operation according to some embodiments. As shown, after a program or erase operation each sector (304, 306, 308, 310) may contain up to N single bit errors and the operation will still be considered to be a success. Here, N is equal to the maximum number of bits that may be corrected using the system's ECC scheme. This number may depend on system capabilities and/or the chosen ECC scheme, and may be determined by the system or by a user of the system. The ECC region of the page (312) may be used to store error correction data to be used in the ECC operation.

Thus, after a program or erase operation, a page may contain up to N errors per sector, or up to 4N total errors equally divided between sectors, and the operation will still be considered successful. The errors in each sector may be corrected during an ECC operation. This may provide higher silicon yields during the manufacturing and testing process, and may also provide higher reliability and longevity in end user systems that include ECC capable memory devices.

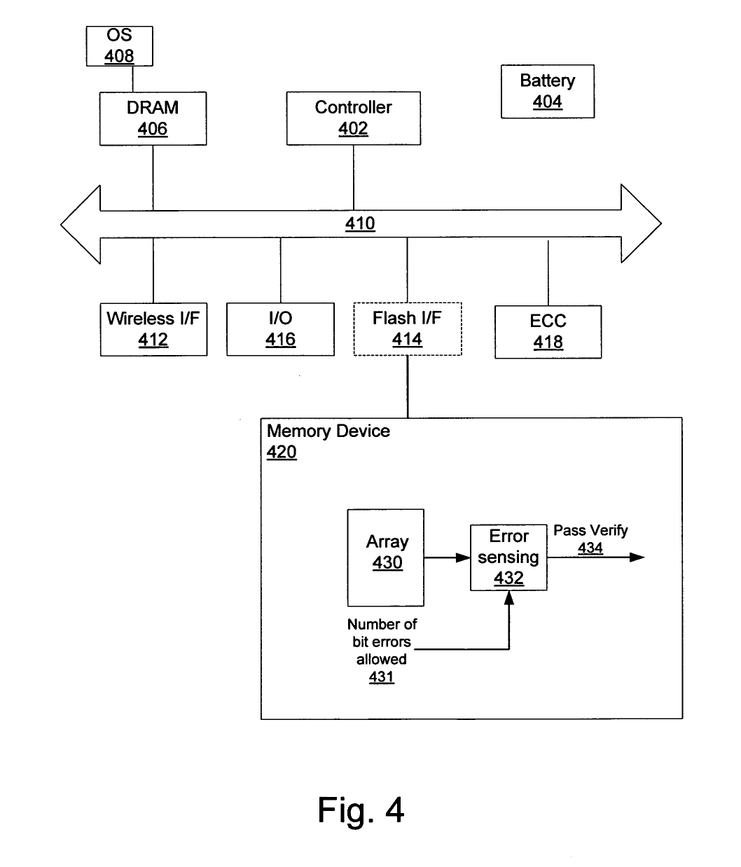

FIG. 4 is a block diagram of a system according to one embodiment. The system may include a controller (402) which communicates via an interconnect (410). The controller (402) may be a microcontroller, one or more microprocessors, a multi-core microprocessor, a digital signal processor (DSP), or another type of controller. The system may be powered by a battery (404) or may be powered with another power source, such as AC power.

System memory or dynamic random access memory (DRAM) (406) may be coupled to the interconnect (410). The DRAM (406) may store an operating system (OS) (408) after system initialization.

A variety of input/output (I/O) devices (416) may be coupled to the interconnect (410). The I/O devices may include items such as a display, keyboard, mouse, touch screen, or other I/O devices. A wireless network interface (412) may also be coupled to the interconnect (410). The wireless interface (412) may enable cellular or other wireless communication between the system and other devices. In one embodiment, the wireless interface (412) may include a dipole antenna.

The system also includes a non-volatile memory device (420) capable of supporting ECC, such as, but not limited to, a NAND flash memory device. The memory device may be built into the system, or may be part of a removable storage medium, such as a card form factor, that may be inserted into an optional flash card interface or other type of interface.

The memory device (420) may include a memory array (430) and error sensing logic (432) coupled to the array. The memory device may include other elements as well, however, those components are not illustrated here for ease of understanding.

The sector sensing logic (432) may be used to determine the number of single bit errors in each of a plurality of sectors in a page read from the memory array during a program or erase verify operation. The number of errors per sector may then be compared to an allowable number of bit errors (431) to determine if the number of errors in each sector is acceptable. If each sector contains an acceptable number of errors, a page verify signal (434) will indicate that the program or erase operation was successful. If one or more sectors contains greater than an allowable number of errors, the page verify signal (434) will indicate that the program or erase operation failed.

The allowable number of errors per sector (431) may be set by a component in the system, such as, for example, by the controller (402). In other embodiments, the allowable number of errors per sector (431) may be set by a user of the system.

In some embodiments, an ECC module (418) may also be coupled to the interconnect (410) and/or the memory device (420) to provide error correction capability in the system. In some embodiments, the ECC module may be implemented in hardware. In other embodiments, ECC may be implemented in software. The ECC module may, in some embodiments, be integrated into the memory device (420).

The methods set forth above may be implemented via instructions stored on a machine-accessible medium which are executed by a processor. The instructions may be implemented in many different ways, utilizing any programming code stored on any machine-accessible medium. A machine-accessible medium includes any mechanism that provides (i.e., stores and/or transmits) information in a form readable by a machine, such as a computer. For example, a machine-accessible medium includes random-access memory (RAM), such as static RAM (SRAM) or dynamic RAM (DRAM); ROM; magnetic or optical storage medium; flash memory devices; electrical, optical, acoustical or other form of propagated signals (e.g., carrier waves, infrared signals, digital signals); etc.

Thus, a method, apparatus, and system for detecting errors per sector in a memory device are disclosed in various embodiments. In the above description, numerous specific details are set forth. However, it is understood that embodiments may be practiced without these specific details. In other instances, well-known circuits, structures, and techniques have not been shown in detail in order not to obscure the understanding of this description. Embodiments have been described with reference to specific exemplary embodiments thereof. It will, however, be evident to persons having the benefit of this disclosure that various modifications and changes may be made to these embodiments without departing from the broader spirit and scope of the embodiments described herein. The specification and drawings are, accordingly, to be regarded in an illustrative rather than a restrictive sense.

I claim:

1. A method comprising:
reading a page from a memory array, wherein the page includes a plurality of sectors;
determining whether each of the plurality of sectors includes an acceptable number of errors; and
providing a success indicator if each of the plurality of sectors includes the acceptable number of errors.

2. The method of claim 1, wherein reading the page from the memory array occurs while performing a program verify operation.

3. The method of claim 1, wherein determining whether each of the plurality of sectors includes the acceptable number of errors comprises comparing a total number of errors in each sector with a maximum number of acceptable errors for each sector.

4. The method of claim 3, wherein the maximum number of acceptable errors for each sector is equal to the number of errors in each sector that may be corrected using ECC.

5. The method of claim 3, wherein the maximum number of acceptable errors for each sector is determined by a user.

6. The method of claim 1, wherein providing the success indicator comprises writing a value to a status register.

7. The method of claim 1, further comprising providing a failure indicator if at least one of the plurality of sectors includes greater than the acceptable number of errors.

8. The method of claim 1, further comprising performing an ECC operation to correct up to the acceptable number of errors in each of the plurality of sectors.

9. An apparatus comprising:
a memory array; and
logic coupled to the memory array, the logic to determine a number of errors in each of a plurality of sectors in a page read from the memory array and to indicate if the number of errors in each of the plurality of sectors is an acceptable number of errors.

10. The apparatus of claim 9, wherein the logic includes a comparator to compare the number of errors in each of the plurality of sectors with a maximum number of acceptable errors for each sector.

11. The apparatus of claim 10, wherein the maximum number of acceptable errors for each sector is equal to the number of errors in each sector that may be corrected using ECC.

12. The apparatus of claim 10, wherein the maximum number of acceptable errors for each sector is determined by a user.

13. The apparatus of claim 9, wherein the logic is further to indicate if the number of errors in each of the plurality of sectors is less than or equal to the acceptable number of errors by writing a value to a status register.

14. The apparatus of claim 9, wherein the logic is further to indicate if the number of errors in each of the plurality of sectors is greater than the acceptable number of errors.

15. A system comprising:
an interconnect;
a processor coupled to the interconnect;
a wireless interface coupled to the interconnect; and
a memory device coupled to the interconnect, wherein the memory device includes a memory array and logic coupled to the memory array, the logic to determine a number of errors in each of a plurality sectors in a page read from the memory array and to indicate if the number of errors in each of the plurality of sectors is an acceptable number of errors.

16. The system of claim 15, wherein the memory device is a NAND flash memory device.

17. The system of claim 15, further comprising an error control coding (ECC) module coupled to the interconnect.
